(19) United States
(12) Patent Application Publication
(10) Pub. No.: US 2026/0290463 A1
(43) Pub. Date: Sep. 24, 2026

(54) MEMORY DEVICE AND METHOD OF CONTROLLING THE SAME

(71) Applicant: Kioxia Corporation, Tokyo (JP)

(72) Inventor: Reiko KOMIYA, Nagoya (JP)

(73) Assignee: Kioxia Corporation, Tokyo (JP)

(21) Appl. No.: 19/331,508

(22) Filed: Sep. 17, 2025

(30) Foreign Application Priority Data
Mar. 21, 2025 (JP) 2025-047001

(51) Int. Cl. G11C 16/16; G11C 16/24; G11C 16/34

(52) U.S. Cl. CPC G11C 16/16; G11C 16/24; G11C 16/3404

(57) ABSTRACT

A memory device includes a bit line extending in a first direction; a memory cell array region including a first region including a first block, a second region including a second block, and a third region disposed between the first region and the second regions and including a third block, the first to third regions disposed in the first direction; and a storage unit configured to store a parameter regarding a first erasing voltage applied to the first block and the second block and a second erasing voltage applied to the third block, wherein the first erasing voltage is different from the second erasing voltage. The first region is disposed on an edge side of the memory cell array region in a direction opposite to the first direction. The second region is disposed on an edge side of the memory cell array region in the first direction.

### CROSS-REFERENCE TO RELATED APPLICATION

This application is based upon and claims the benefit of priority from Japanese Patent Application No. 2025-047001, filed Mar. 21, 2025, the entire contents of which are incorporated herein by reference.

### FIELD

Embodiments described herein relate generally to a memory device and a method of controlling the same.

### BACKGROUND

A NAND flash memory is known as one of memory devices. In the NAND flash memory, a data erase operation is executed in units of blocks.

### DESCRIPTION OF THE DRAWINGS

FIG. 1 is a block diagram illustrating a NAND flash memory according to an embodiment;

FIG. 2 is a block diagram illustrating a memory cell array according to the embodiment;

FIG. 3 is a circuit diagram illustrating one block in the memory cell array according to the embodiment;

FIG. 4 is a schematic plan view illustrating a region where there are a plurality of blocks in the memory cell array according to the embodiment;

FIG. 5 is a diagram schematically illustrating an example of a threshold voltage distribution of memory cell transistors in an edge block and a middle block before an erasing voltage is applied;

FIG. 6 is a diagram schematically illustrating another example of the threshold voltage distribution of the memory cell transistors in the edge block and the middle block before the erasing voltage is applied;

FIG. 7 is a diagram schematically illustrating an example of the threshold voltage distribution of the memory cell transistors in the edge block and the middle block after the erasing voltage is applied;

FIG. 8 is a diagram schematically illustrating another example of the threshold voltage distribution of the memory cell transistors in the edge block and the middle block after the erasing voltage is applied;

FIG. 9 is a schematic plan view illustrating a plane region according to the embodiment;

FIG. 10 is a perspective view schematically illustrating a part of the NAND flash memory according to the embodiment;

FIG. 11 is an XY plan view illustrating the memory cell array according to the embodiment;

FIG. 12 is a ZX sectional view illustrating the memory cell array according to the embodiment;

FIG. 13 is an XY plan view illustrating the memory cell array according to the embodiment;

FIG. 14 is a circuit diagram illustrating a configuration of a block when the number of drain-side select transistor and the number of a source-side select transistor are each 2;

FIGS. 15A and 15B are waveform diagrams illustrating examples of erasing voltages applied to an edge block, a center block, a middle block, and a wiring when an edge erasing voltage is higher than center/middle block erasing voltages;

FIGS. 16A and 16B are waveform diagrams illustrating examples of erasing voltages applied to the edge block, the center block, the middle block, and the wiring when the edge erasing voltage is higher than center/middle block erasing voltages; and

FIGS. 17A and 17B are waveform diagrams illustrating examples of erasing voltages applied to edge blocks, center blocks, middle blocks, and wirings of a plurality of plane regions.

### DETAILED DESCRIPTION

Embodiments provide a memory device capable of improving reliability of a memory cell transistor and executing a data erase operation and a method of controlling the same.

In general, according to one embodiment, a memory device includes a bit line extending in a first direction; a memory cell array region including a first region including a first block, a second region including a second block, and a third region disposed between the first region and the second regions and including a third block, each of the first to third blocks being configured an erasing unit, wherein the first region, the second region, and the third region are disposed in the first direction and each of the first block, the second block, and the third block includes a plurality of memory transistors to store data; and a storage unit configured to store a parameter regarding a first erasing voltage applied to the first block and the second block during an erase operation on the first block and the second block and a second erasing voltage applied to the third block during an erase operation on the third block, wherein the first erasing voltage is different from the second erasing voltage. The first region is disposed on an edge side of the memory cell array region in a direction opposite to the first direction. The second region is disposed on an edge side of the memory cell array region in the first direction.

Hereinafter, embodiments will be described with reference to the drawings. The drawings are schematic or conceptual and are not limited and may not necessarily be identical to the actual ones. In the drawings, the same reference numerals are given to the same or equivalent portions, and repeated description will be made as necessary. For simplification, reference numerals are not given to the same or equivalent portions in some cases.

### First Embodiment

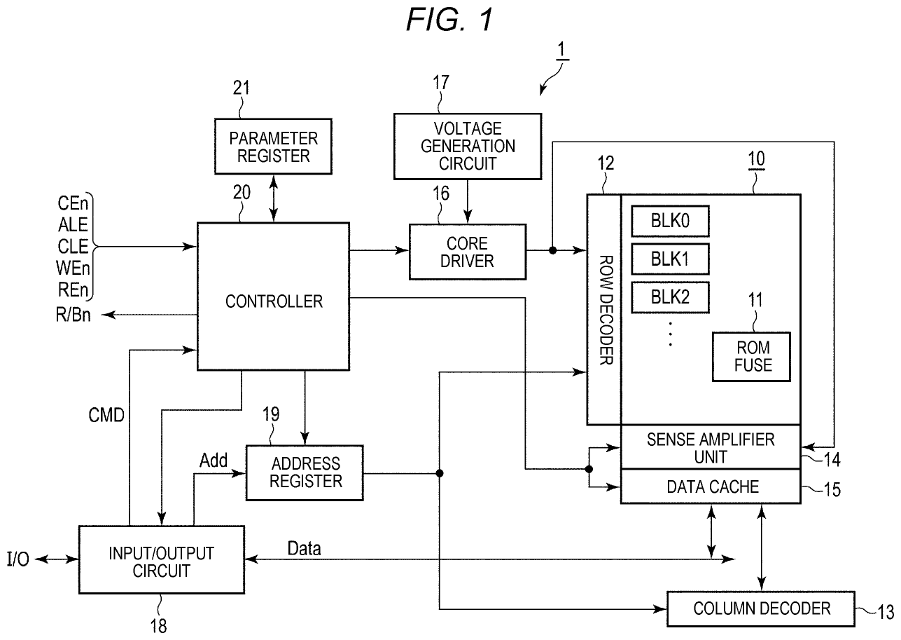

FIG. 1 is a block diagram illustrating a NAND flash memory (memory device) 1 according to an embodiment. The NAND flash memory 1 is a memory device capable of storing data in a nonvolatile manner.

The NAND flash memory 1 includes a memory cell array 10, a row decoder 12, a column decoder 13, a sense amplifier unit 14, a data cache 15, a core driver 16, a voltage generation circuit 17, an input/output circuit 18, an address register 19, a controller 20, and a parameter register 21.

The memory cell array 10 includes a plurality of memory cell transistors (not illustrated). The plurality of memory cell transistors are classified into a plurality of blocks BLK0, BLK1, BLK2, . . . that are erasing units of data. Hereinafter, when it is not necessary to distinguish the blocks BLK0, BLK1, BLK2, . . . from each other, the blocks BLK0, BLK1, BLK2, . . . are referred simply to as the BLK. The blocks BLK0, BLK1, BLK2, . . . are simply referred to the blocks in some cases. In the embodiment, the number of memory cell arrays 10 (planes) is 1.

The memory cell array 10 further includes a ROM fuse 11. In the ROM fuse 11, information (parameters) related to various essential settings is stored in advance in order to normally control the NAND flash memory 1. In the embodiment, the ROM fuse 11 stores information related to a setting of a voltage (erasing voltage) applied to the block BLK during an erase operation. As the information related to the setting of the erasing voltage, information related to a setting of an erasing voltage not including a correction voltage and information related to a setting of an erasing voltage including the correction voltage is stored. The correction voltage will be described below.

In the memory cell array 10, bit lines, word lines, and source lines are laid in order to control voltages applied to the memory cell transistors. A specific configuration of the memory cell array 10 will be described below.

The row decoder 12 receives a block address signal and a row address signal from the address register 19 and selects any word line in a corresponding block based on the block address signal and the row address signal. The column decoder 13 receives a column address signal from the address register 19 and selects any bit line based on the column address signal.

The sense amplifier unit 14 detects and amplifies data read from memory cell transistors to a bit line during reading of data. The sense amplifier unit 14 transfers write data to a bit line during writing of data. The reading and writing of data from and on the memory cell array 10 are executed in units of a plurality of memory cell transistors, and the units are a page.

The data cache 15 stores data in units of pages. During reading of data, the data cache 15 temporarily stores data transferred from the sense amplifier unit 14 in units of pages and transfers the data to the input/output circuit 18. During writing of data, the data cache 15 temporarily stores data transferred from the input/output circuit 18 in series and transfers the data to the sense amplifier unit 14 in units of pages.

The core driver 16 supplies voltages necessary for writing, reading, and erasing data to the row decoder 12, the sense amplifier unit 14, and the like. The voltages supplied by the core driver 16 are applied to a word line, a select gate line, a bit line, and the like via the row decoder 12, the sense amplifier unit 14, and the like.

The voltage generation circuit 17 generates internal voltages (for example, voltages for boosting a power voltage) necessary for each operation and supplies the internal voltages to the core driver 16.

The controller 20 controls an overall operation of the NAND flash memory 1. The controller 20 receives various external control signals, for example, a chip enable signal CEn, an address latch enable signal ALE, a command latch enable signal CLE, a write enable signal WEn, and a read enable signal REn, from an external host device (not illustrated). “n” suffixed to a signal name indicates an active low.

The controller 20 identifies an address Add and a command CMD supplied from an input/output terminal I/O based on the external control signals. The controller 20 transfers the address Add to the column decoder 13 and the row decoder 12 via the address register 19. The controller 20 decodes the command CMD. The controller 20 executes each sequence control of reading, writing, and erasing of data in accordance with the external control signal and the command CMD. The controller 20 outputs a ready/busy signal R/Bn in order to notify the host device of an operation state of the NAND flash memory 1. The host device can ascertain a state of the NAND flash memory 1 by receiving the ready/busy signal R/Bn.

The input/output circuit 18 transmits and receives data (including the command CMD, the address Add, and data) via a NAND bus to and from the host device.

The parameter register 21 temporarily stores information related to a setting read from the ROM fuse 12 of the memory cell array 10, for example, during power-ON. The parameter register 21 temporarily stores various types of data necessary for an operation of the memory cell array 10. The parameter register 21 is configured with, for example, an SRAM.

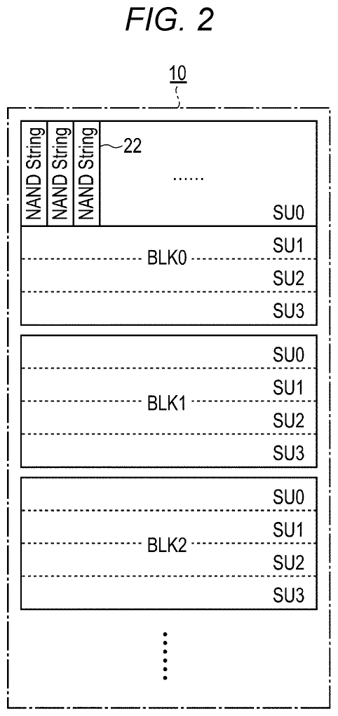

FIG. 2 is a block diagram illustrating the memory cell array 10 according to the embodiment. The memory cell array 10 includes a plurality of blocks BLK (BLK0, BLK1, BLK2, . . . ). Each of the plurality of blocks BLK includes a plurality of string units SU (SU0, SU1, SU2, . . . ). Each of the plurality of string units SU includes a plurality of NAND strings 22. The number of blocks in the memory cell array 10, the number of string units in one block BLK, and the number of NAND strings in one string unit SU can each be set to any number.

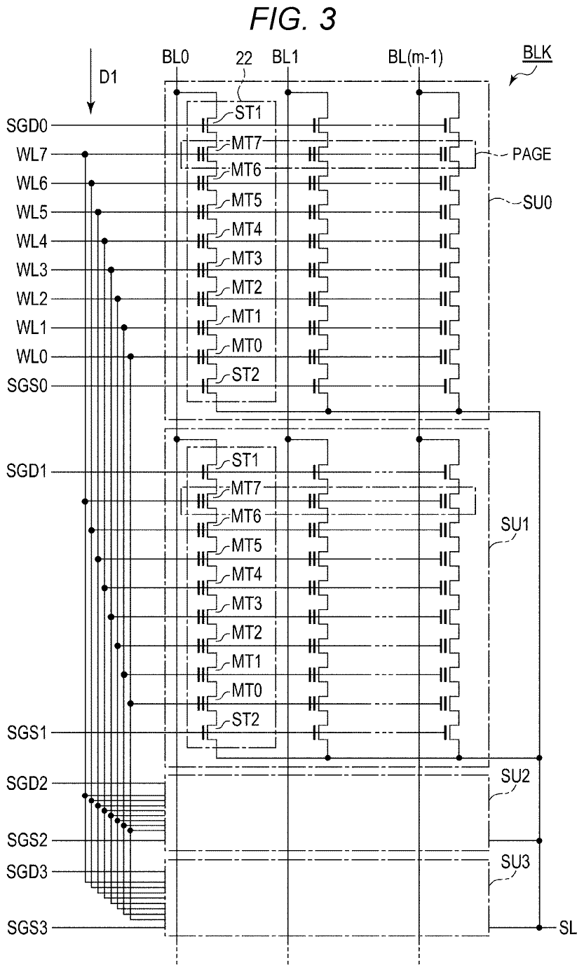

FIG. 3 is a circuit diagram illustrating one block BLK in the memory cell array 10 according to the embodiment. Each of the plurality of NAND strings 22 includes a plurality of memory cell transistors MT and two select transistors ST1 and ST2. In FIG. 3, a configuration example in which the NAND string 22 includes eight memory cell transistors MT (MT0 to MT7) is illustrated. The number of memory cell transistors MT in the NAND string 22 can be set to any number. The memory cell transistor MT includes a control gate and a charge storage layer and stores data in a nonvolatile manner. The memory cell transistors MT may store 1-bit data (binary) or may store 2 or more-bit data (or ternary or more).

The plurality of memory cell transistors MT are arrayed so that current paths of the memory cell transistors MT are connected in series between the select transistors ST1 and ST2. The current paths of the memory cell transistors MT on one side of the series connection are connected to one end of a current path of the select transistor ST1 and the current paths of the memory cell transistors MT on the other side are connected to one end of a current path of the select transistor ST2.

Gates of the plurality of select transistors ST1 in the string unit SU0 are connected in common to a select gate line SGD0. Similarly, select gate lines SGD1 to SGD3 are connected to the string units SU1 to SU3, respectively. Hereinafter, the select gate lines SGD0 to SGD3 are simply referred to the select gate lines SGD in some cases. The gates of the plurality of select transistors ST2 in the string unit SU0 are connected to the select gate line SGS0 in common. Similarly, select gate lines SGS1 to SGS3 are connected to the string units SU1 to SU3, respectively. Hereinafter, the select gate lines SGS0 to SGS3 are simply referred to as the select gate lines SGS in some cases. Gates of the plurality of select transistors ST2 in the same block BLK may be connected to the same select gate line SGS in common. Control gates of the memory cell transistors MT0 to MT7 in the same block BLK are connected to word lines WL0 to WL7, respectively.

The other ends of the current paths of the select transistors ST1 of the plurality of NAND strings 22 at the same column among the NAND strings 22 arrayed in a matrix configuration in the memory cell array 10 are connected to any of the bit lines BL0, BL1, . . . , BL(m−1) in common (where “m” is an integer of 2 or more). Hereinafter, when it is not necessary to distinguish the bit lines BL0, BL1, . . . , BL(m−1) from each other, the bit lines BL0, BL1, . . . , BL(m−1) are referred to as the BL. The bit line BL extends in the first direction D1.

One bit line BL is connected to the NAND strings 22 at the same column in common between the plurality of blocks BLK. The other ends of the current paths of the plurality of select transistors ST2 in the same block BLK are connected to the source line SL in common. The source line SL connects the plurality of NAND strings 22 in common, for example, between a plurality of blocks.

Data of the plurality of memory cell transistors MT in the same block BLK is erased collectively. Reading and writing of data are executed collectively on the plurality of memory cell transistors MT connected in common to one word line WL laid in one string unit SU. Units of data are referred to as a page.

In the example of FIG. 3, two select transistors ST1 and ST2 are used. As illustrated in FIG. 14, the select transistor ST1 (drain-side select transistor) may be changed to two select transistors (drain-side select transistors) ST1a and ST1b, the select transistor ST2 (source-side select transistor) may be changed to two select transistors (source-side select transistors) ST2a and ST2b, the select gate line SGD (drain-side select gate line) may be changed to two select gate lines (drain-side select gate lines) SGD and SGDT, and the select gate line SGS (source-side select gate line) may be changed to two select gate lines (source-side select gate lines) SGS and SGSB.

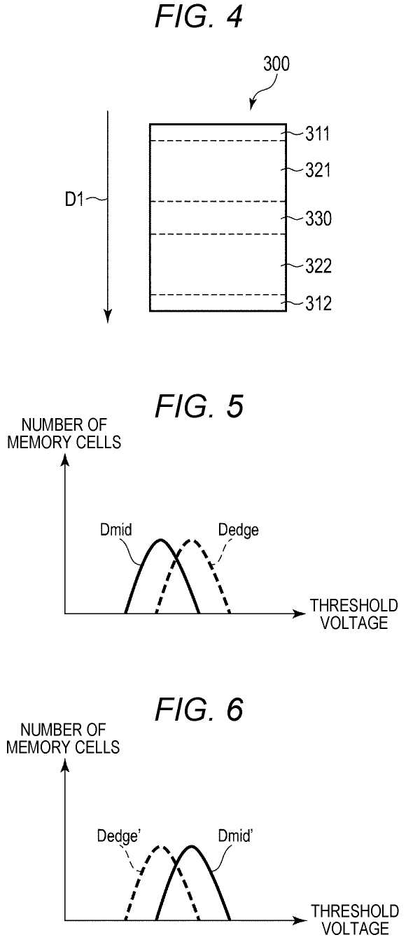

FIG. 4 is a schematic plan view illustrating a region (plane region) 300 where there are a plurality of blocks in the memory cell array according to the embodiment. The plane region 300 includes a first edge plane region 311, a first middle plane region 321, a center plane region 330, a second middle plane region 322, and a second edge plane region 312.

Hereinafter, a block located in the first edge plane region 311 is referred to as an edge block, and a block located in the first middle plane region 321 is referred to as a middle block. Similarly, a block located in the second edge plane region 312 is referred to as an edge block, and a block located in the second middle plane region 322 is referred to as a middle block. A block located in the center plane region 330 is referred to as a center block.

The first edge plane region 311, the first middle plane region 321, the center plane region 330, the second middle plane region 322, and the second edge plane region 312 are disposed in sequence in an extension direction D1 of the bit line.

The center plane region 330 is disposed between the first edge plane region 311 and the second edge plane region 312. The first middle plane region 321 is disposed between the first edge plane region 311 and the center plane region 330. The second middle plane region 322 is disposed between the center plane region 330 and the second edge plane region 312.

A sum (N1) of the number of middle blocks and the number of center blocks is greater than the number (N2) of edge blocks (where N1>N2). A ratio of N1 to N2 is, for example, N1:N2=25:75.

Therefore, an erasing voltage is determined based on erasing characteristics of the memory cell transistors in the middle blocks and erasing characteristics of the memory cell transistors in the center block. The erasing characteristics are determined in accordance with, for example, a threshold voltage of the memory cell transistor.

FIG. 5 is a diagram schematically illustrating an example of a threshold voltage distribution of memory cell transistors in an edge block and a middle block before an erasing voltage is applied. In FIG. 5, Dedge indicates a threshold voltage distribution of the memory cell transistors in the edge block, and Dmid indicates a threshold voltage distribution of the memory cell transistor in the middle block. The horizontal axis represents a threshold voltage of the memory cell transistor. The vertical axis represents the number of memory cell transistors (the number of memory cells).

As illustrated in FIG. 5, when the threshold voltage distribution Dedge and the threshold voltage distribution Dmid are compared, the threshold voltage distribution Dedge deviates from the threshold voltage distribution Dmid in a direction in which a threshold voltage rises. In this case, a threshold voltage at which the number of memory cells is the maximum in the threshold voltage distribution Dedge is higher than a threshold voltage at which the number of memory cells is the maximum in the threshold voltage distribution Dmid, and there is a variation in the threshold voltage distribution between the edge block and the middle block.

Therefore, when erase operations of the edge block and the middle block are executed at the same erasing voltage, a state (erasing state) of the memory cell transistors of the edge block after the erase operation is likely to become an erasing deficient state. To eliminate the erasing deficient state, the number of times of erasing may increase.

However, when the number of times of erasing increases, a time necessary for an erase operation (erasing time) becomes long. As a result of the increase in the number of times of erasing, an erasing stress applied to the memory cell transistors of a block of the edge region also increases. This results in deterioration in reliability of the memory cell transistors. In FIG. 5, the threshold voltage distribution Dedge and the threshold voltage distribution Dmid are threshold voltage distributions when the same data is written on the edge block and the middle block.

FIG. 6 is a diagram schematically illustrating another example of the threshold voltage distribution of the memory cell transistors in the edge block and the middle block before the erasing voltage is applied.

As illustrated in FIG. 6, when the threshold voltage distribution Dedge and the threshold voltage distribution Dmid are compared, the threshold voltage distribution Dedge deviates from the threshold voltage distribution Dmid in a direction in which the threshold voltage lowers. In this case, a threshold voltage at which the number of memory cells is the maximum in the threshold voltage distribution Dedge is lower than a threshold voltage at which the number of memory cells is the maximum in the threshold voltage distribution Dmid, and there is a variation in the threshold voltage distribution between the edge block and the middle block.

Therefore, when an erase operation is executed on the edge block and the middle block at the same erasing voltage, a state (erasing state) of the memory cell transistors of the edge block after the erase operation is likely to become an over-erasing state. In the over-erasing state, an erasing stress applied to the memory cell transistors of the edge block increases. This results in deterioration in reliability of the memory cell transistors.

Accordingly, in the embodiment, in order to prevent the state of the memory cell transistors in the edge block after the erase operation from becoming the erasing deficient state or the over-erasing state, an erasing voltage applied to the memory cell transistors in the edge block and an erasing voltage applied to the memory cell transistors in the center block are changed. Specifically, it is as follows.

First, as illustrated in FIG. 5, a case where the threshold voltage distribution Dedge deviates from the threshold voltage distribution Dmid in the direction in which the threshold voltage rises will be described. In this case, an erasing voltage applied to the memory cell transistors in the edge block (hereinafter also referred to as an edge block erasing voltage) is set to be higher than an erasing voltage applied to the memory cell transistors in the middle block (hereinafter also referred to as a middle block erasing voltage).

For example, it is assumed that Vedge=Verase+ΔV is set when Verase is an erasing voltage determined based on erasing characteristics of the memory cell transistors in the middle block and erasing characteristics of the memory cell transistors in the center block, and Vedge is an edge block erasing voltage. ΔV is a positive correction voltage greater than zero. ΔV is determined in advance based on a calculation result of an erasing voltage of each block of the edge region.

Information regarding Vedge is stored, for example, in the ROM fuse 11. The information regarding Vedge is stored in the ROM fuse 11 in product test processing for selecting a non-defective product and a defective product, for example, in a process of manufacturing the NAND flash memory 1. The information regarding Vedge is, for example, Verase +ΔV. The information regarding Vedge may also be Verase and ΔV. In this case, Verase+ΔV is calculated from Verase and ΔV read from the ROM fuse 11.

Verase is determined based on, for example, erasing characteristics of the memory cell transistors in the middle block and erasing characteristics of the memory cell transistors of the center block. Therefore, a variation in a threshold voltage distribution between the center block and the middle block is less than a variation in a threshold voltage distribution between the edge block and the middle block. Accordingly, in the embodiment, an erasing voltage applied to the memory cell transistors in the center block (hereinafter also referred to as a center block erasing voltage) is the same as the middle block erasing voltage. Hereinafter, the center block erasing voltage and the middle block erasing voltage are also referred to as a center/middle block erasing voltage. The center block and the middle block are also referred to as a center/middle block.

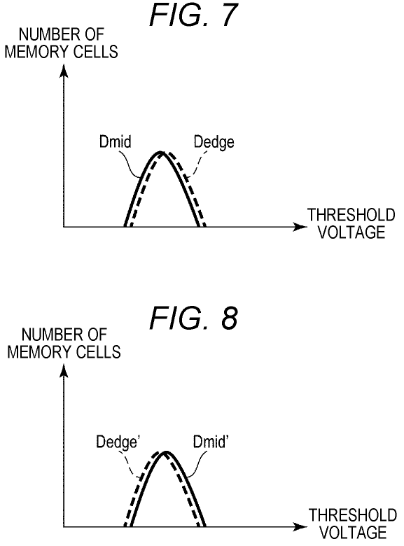

FIG. 7 is a diagram schematically illustrating the threshold voltage distributions Dedge and Dmid of the memory cell transistors in the edge block and the middle block after application of an erasing voltage (Verase, Verase+ΔV) according to the embodiment when the threshold voltage at which the number of memory cells is the maximum in the threshold voltage distribution Dedge is higher than a threshold voltage at which the number of memory cells is the maximum in the threshold voltage distribution Dmid. Hereinafter, an erasing voltage applied to the memory cell transistors in the center block is also referred to as a center block erasing voltage.

As illustrated in FIG. 7, deviation of the threshold voltage distributions Dedge from the threshold voltage distributions Dmid in the direction in which the threshold voltage rises is less than deviation of the threshold voltage distributions Dedge from the threshold voltage distribution Dmid in the direction in which the threshold voltage rises in FIG. 5. In this way, according to the embodiment, a variation in the threshold voltage distribution between the edge block and the middle block can be decreased.

Accordingly, according to the embodiment, it is possible to prevent the memory cell transistors in the block of the edge region after the erase operation from entering the erasing deficient state. As a result, it is possible to obtain advantages such as improvement in reliability of the memory cell transistor of the edge block and a reduced erasing time.

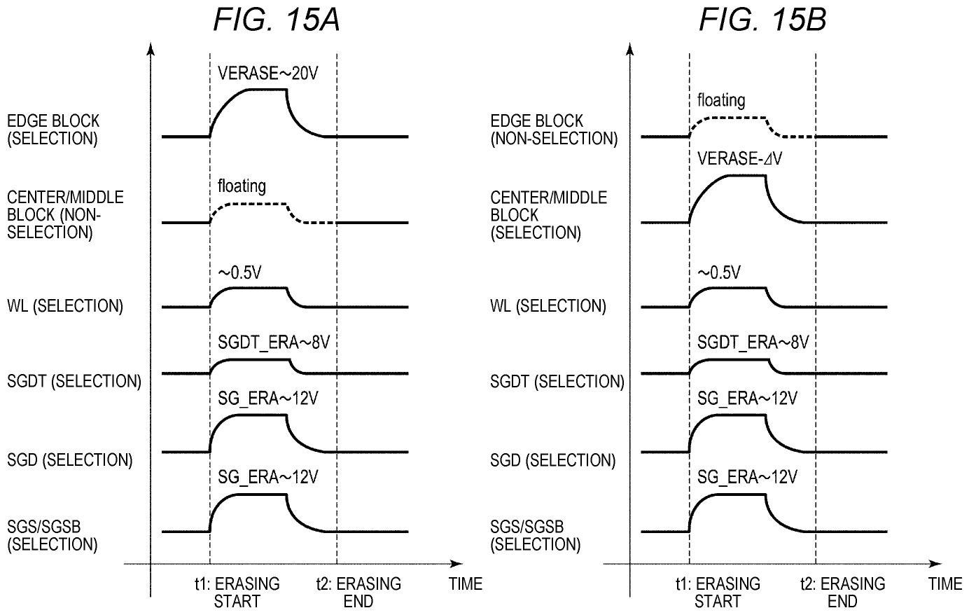

FIG. 15A is a waveform diagram illustrating examples of erasing voltages applied to an edge block and each wiring (a WL wiring, an SGDT wiring, an SGD wiring, an SGS wiring, and an SGSB wiring) during execution of an erase operation on the edge blocks 311 and 312 (hereinafter simply referred to as the edge blocks) of FIG. 4 when an edge erasing voltage is higher than the center/middle block erasing voltage.

FIG. 15B is a waveform diagram illustrating an example of an erasing voltage applied to the center block, the edge block and each wiring (WL, SGDT, SGD, SGS, and SGSB) during execution of an erase operation on the center block 30 and middle blocks 321 and 322 of FIG. 4 when the edge erasing voltage is higher than the center/middle block erasing voltage.

FIGS. 15A and 15B are waveform diagrams when each of the number of drain-side select transistors and the number of source-side select transistors is 2, as illustrated in FIG. 14. In FIGS. 15A and 15B, SGDT_ERA indicates a voltage applied to the drain-side select gate line SGDT, SG_ERA indicates a voltage applied to the drain-side select gate line SGD, and SG_ERA indicates a voltage applied to the source-side select gate line SGS and SGSB. In FIGS. 15A and 15B, a voltage applied to the edge block is VERASE (corresponding to Verase+ΔV).

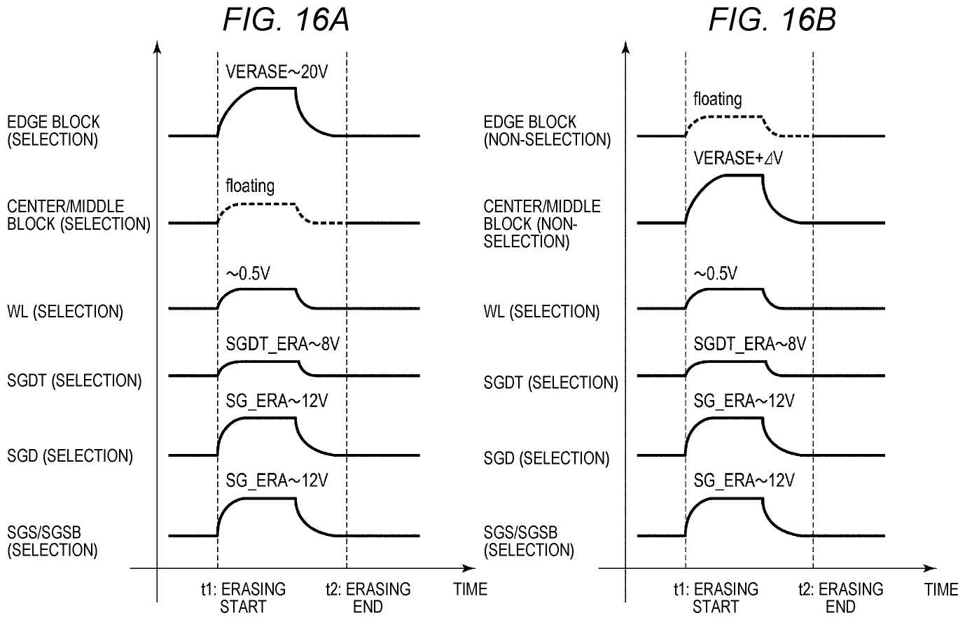

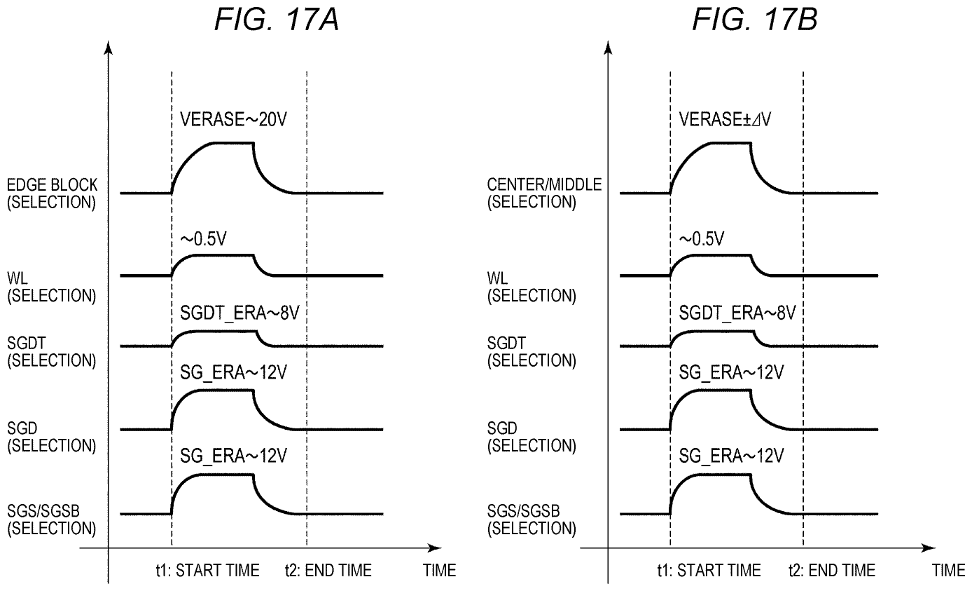

FIGS. 16 and 17 are also waveform diagrams when each of the number of drain-side select transistors and the number of source-side select transistors is 2 similarly.

When the edge erasing voltage is higher than the center/middle block erasing voltage, for example, as illustrated in FIG. 15A, VERASE (for example, 20 V) is applied to the edge block to set the center/middle block to a floating state (non-selection), a voltage (for example, 0.5 V) is applied to a WL to select the WL, SGDT_ERA (for example, 8 V) is applied to an SGDT to select the SGDT, and SG_ERA (for example, 12 V) is applied to an SGD, an SGS, and an SGSB to select the SGD, the SGS, and the SGSB at time t1 during execution of an erase operation on the edge block. After a given period passes from time t1, the application of the voltages stops and the erase operation ends at time t2.

When the edge erasing voltage is higher than the center/middle block erasing voltage, for example, as illustrated in FIG. 15B, the edge block is set to a floating state (non-selection), Verase−ΔV is applied to the center/middle block, a voltage (for example, 0.5 V) is applied to a WL to select the WL, SGDT_ERA (for example, 8 V) is applied to an SGDT to select the SGDT, and 12 V is applied to an SGD, an SGS, and an SGSB to select the SGD, the SGS, and the SGSB during execution of an erase operation on the center/middle block. After a given period passes from time t1, the application of the voltages stops and the erase operation ends at time t2.

On the other hand, as illustrated in FIG. 6, when the threshold voltage distribution Dedge deviates from the threshold voltage distribution Dmid in a direction in which the threshold voltage lowers, the edge block erasing voltage becomes lower than the middle block erasing voltage. For example, Vedge=Vmid−ΔV is set.

Information regarding Vedge is stored, for example, in the ROM fuse 11. The information regarding Vedge is, for example, Verase−ΔV. The Information regarding Vedge may be Verase and ΔV. In this case, Verase−ΔV is calculated from Verase and ΔV read from the ROM fuse 11.

FIG. 8 is a diagram schematically illustrating a threshold voltage distributions Dedge and Dmid of the memory cell transistors in the edge block and the middle block after application of an erasing voltage (Verase, Verase−ΔV) according to the embodiment when the threshold voltage at which the number of memory cells is the maximum in the threshold voltage distribution Dedge is lower than a threshold voltage at which the number of memory cells is the maximum in the threshold voltage distribution Dmid.

As illustrated in FIG. 8, deviation of the threshold voltage distributions Dedge from the threshold voltage distributions Dmid in the direction in which the threshold voltage lowers is less than deviation of the threshold voltage distributions Dedge from the threshold voltage distribution Dmid in the direction in which the threshold voltage lowers in FIG. 6. In this way, according to the embodiment, a variation in the threshold voltage distribution between the edge block and the middle block can be decreased.

Accordingly, according to the embodiment, it is possible to prevent the memory cell transistors in the block of the edge region after the erase operation from entering the over-erasing state. As a result, it is possible to obtain advantages such as reduction in an erasing stress applied to the memory cell transistors of the edge block and improvement in reliability of the memory cell transistors.

FIG. 16A is a waveform diagram illustrating examples of voltages applied to an edge block and each wiring (a WL wiring, an SGDT wiring, an SGD wiring, an SGS wiring, and an SGSB wiring) when an edge erasing voltage is lower than the center/middle block erasing voltage and an erase operation is executed on the edge block.

FIG. 16B is a waveform diagram illustrating examples of erasing voltages applied to the center block, the edge block, and each wiring (WL, SGDT, SGD, SGS, and SGSB) during execution of an erase operation on the center/middle block when the edge erasing voltage is lower than the center/middle block erasing voltage. In FIGS. 16A and 16B, a voltage applied to the edge block is VERASE.

When the edge erasing voltage is lower than that in the center/middle block, for example, as illustrated in FIG. 16A, VERASE (for example, 20 V) is applied to the edge block to set the center block and the middle block to a floating state (selection), a voltage (for example, 0.5 V) is applied to a WL to select the WL, SGDT_ERA (for example, 8 V) is applied to an SGDT to select the SGDT, and SG_ERA (for example, 12 V) is applied to an SGD, an SGS, and an SGSB to select the SGD, the SGS, and the SGSB at time t1 during execution of an erase operation on the edge block. After a given period passes from time t1, the application of the voltages stops and the erase operation ends at time t2. When the edge erasing voltage is lower than the center/middle block erasing voltage, for example, as illustrated in FIG. 16B, the edge block is set to a floating state (non-selection), VERASE+ΔV is applied to the center/middle block, a voltage (for example, 0.5 V) is applied to a WL to select the WL, SGDT_ERA (for example, 8 V) is applied to an SGDT to select the SGDT, and 12 V is applied to an SGD, an SGS, and an SGSB to select the SGD, the SGS, and the SGSB during execution of an erase operation on the center/middle block. After a given period passes from time t1, the application of the voltages stops and the erase operation ends at time t2.

### Second Embodiment

The case where the number of planes (memory cell array regions) of the NAND flash memory is 1 is described in the first embodiment. In the present embodiment, a case where the number of planes of a NAND flash memory is 4 will be described. The number of planes is not limited to 4, and the number of planes may be an integer of 2 or more, such as 2, 6, or 8.

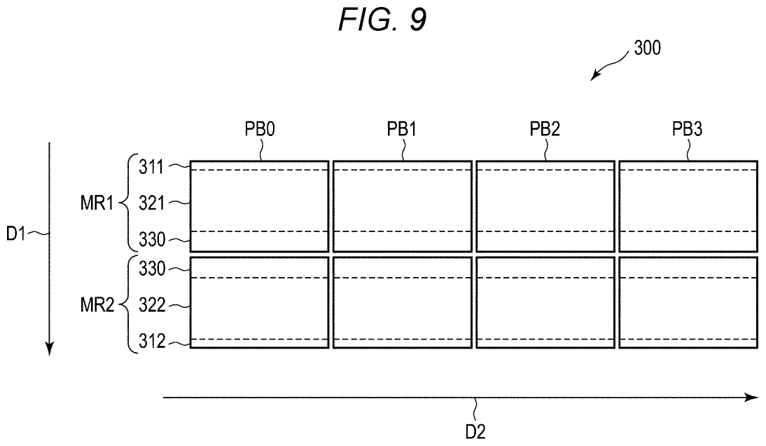

FIG. 9 is a schematic plan view illustrating a plane region 300 according to the embodiment. The plane region 300 includes a plane region PB0, a plane region PB1, a plane region PB2, and a plane region PB3. Hereinafter, when it is not necessary to distinguish the plane regions PB0, PB1, PB2, and PB3 from each other, the plane regions PB0, PB1, PB2, and PB3 are referred to as the PB. The plane regions PB0, PB1, PB2, and PB3 are simply referred to as the planes in some cases.

The plane regions PB0, PB1, PB2, and PB3 are disposed in sequence in a direction D2 in which the word line extends. The plane region PB1 is disposed between the plane regions PB0 and PB3. The plane region PB2 is disposed between the plane regions PB1 and PB3.

The plane region PB0 includes a first memory region MR1 where data is stored and a memory region MR2 where data is stored. In the first memory region MR1 and the second memory region MR2, for example, data with the same number of bytes is stored. The number of bytes is, for example, 8 kB.

As in the plane region 300 illustrated in FIG. 4, the plane region PB0 includes a first edge plane region 311, a first middle plane region 321, a center plane region 330, a second middle plane region 322, and a second edge plane region 312. In FIG. 9, although the center plane region 330 of the first memory region MR1 is separated from the center plane region 330 of the second memory region MR2, the center plane regions 330 are electrically connected to each other.

As described above, when the erase operation is executed on the edge block and the middle block at the same erasing voltage, a state (erasing state) of the memory cell transistors of the edge block after the erase operation becomes an over-erasing state or an erasing deficient state.

Accordingly, in the embodiment, in order to prevent the state of the memory cell transistors in the edge block after the erase operation from becoming the erasing deficient state or the over-erasing state, an erasing voltage applied to the memory cell transistors in the edge block and an erasing voltage applied to the memory cell transistors in the center block are changed. Specifically, it is as follows.

When a threshold voltage distribution of the edge block before application of an erasing voltage deviates from a threshold voltage distribution of the middle block before the application of the erasing voltage in a direction in which the threshold voltage rises, Verase+ΔV is applied as an erasing voltage to the edge block of the plane region PB0, the edge block of the plane region PB1, the edge block of the plane region PB2, and the edge block of the plane region PB3.

On the other hand, Verase is applied to the middle block of the plane region PB0, the middle block of the plane region PB1, the middle block of the plane region PB2, and the middle block of the plane region PB3. Similarly, Verase is applied to the center block of the plane region PB0, the center block of the plane region PB1, the center block of the plane region PB2, and the center block of the plane region PB3.

When a threshold voltage distribution of the edge block before application of an erasing voltage deviates from a threshold voltage distribution of the middle block before the application of the erasing voltage in a direction in which the threshold voltage lowers, Verase−ΔV is applied as an erasing voltage to the edge block of the plane region PB0, the edge block of the plane region PB1, the edge block of the plane region PB2, and the edge block of the plane region PB3.

On the other hand, Verase is applied as an erasing voltage to the middle block of the plane region PB0, the middle block of the plane region PB1, the middle block of the plane region PB2, and the middle block of the plane region PB3. Similarly, Verase is applied as an erasing voltage to the center block of the plane region PB0, the center block of the plane region PB1, the center block of the plane region PB2, and the center block of the plane region PB3.

FIG. 17A is a waveform diagram illustrating examples of voltages applied to the edge block and each wiring (a WL wiring, an SGDT wiring, an SGD wiring, an SGS wiring, and an SGSB wiring) during execution of an erase operation on the edge blocks of the plane regions PB0 to PB3 of FIG. 9. FIG. 17B is a waveform diagram illustrating examples of the center/middle block and each wiring (the WL wiring, the SGDT wiring, the SGD wiring, the SGS wiring, and the SGSB wiring) during execution of an erase operation on the central/middle blocks of the plane regions PB0 to PB3. In FIGS. 17A and 17B, a voltage applied to the edge block is VERASE.

During execution of an erase operation on the edge blocks of the plane regions PB0 to PB3, as illustrated in FIG. 17A, VERASE (for example, 20 V) is applied to the edge blocks of the plane regions PB0 to PB3, a voltage (for example, 0.5 V) is applied to a WL to select the WL, SGDT_ERA (for example, 8 V) is applied to an SGDT to select the SGDT, and SG_ERA (for example, 12 V) is applied to an SGD, an SGS, and an SGSB to select the SGD, the SGS, and the SGSB. After a given period passes from time t1, the application of the voltages stops and the erase operation ends at time t2.

During execution of an erase operation on the center/middle blocks of the plane regions PB0 to PB3, as illustrated in FIG. 17B, at time t1, Verase+ΔV (when the edge erasing voltage is lower than the center/middle block erasing voltage) or VERASE−ΔV (when the edge erasing voltage is higher than the center/middle block erasing voltage) is applied to the center/middle block, a voltage (for example, 0.5 V) is applied to a WL to select the WL, SGDT_ERA (for example, 8 V) is applied to an SGDT to select the SGDT, and 12 V is applied to an SGD, an SGS, and an SGSB to select the SGD, the SGS, and the SGSB. After a given period passes from time t1, the application of the voltages stops and the erase operation ends at time t2.

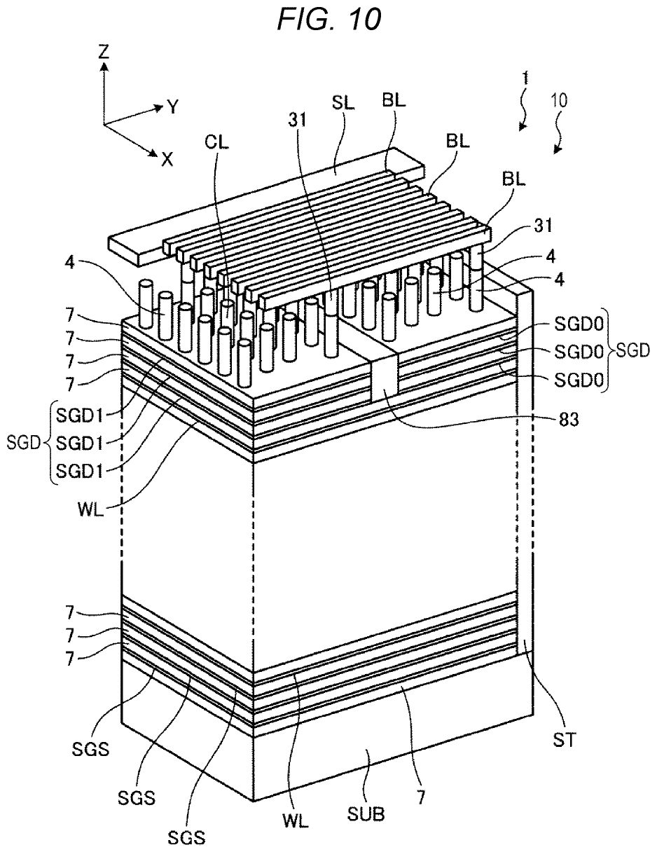

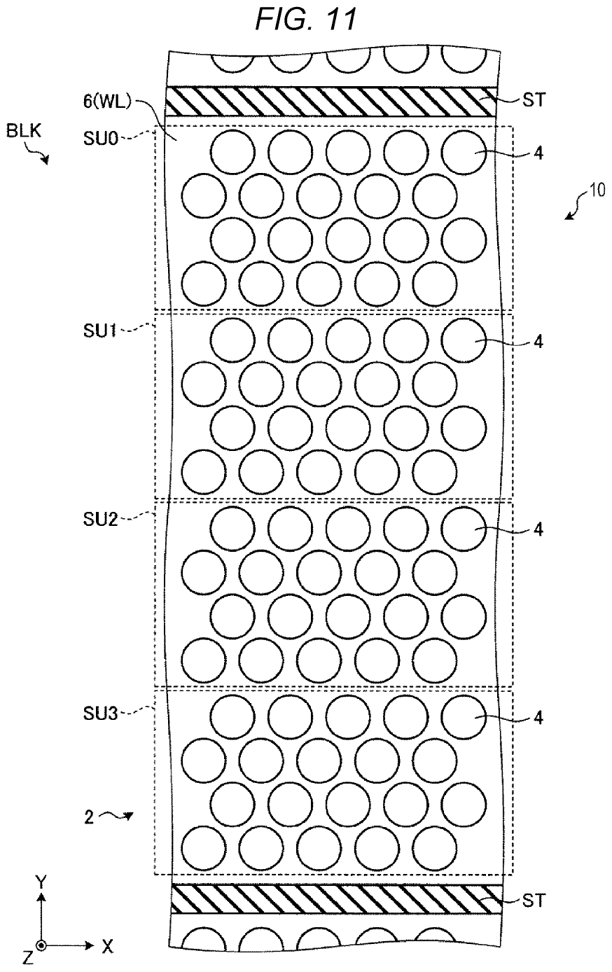

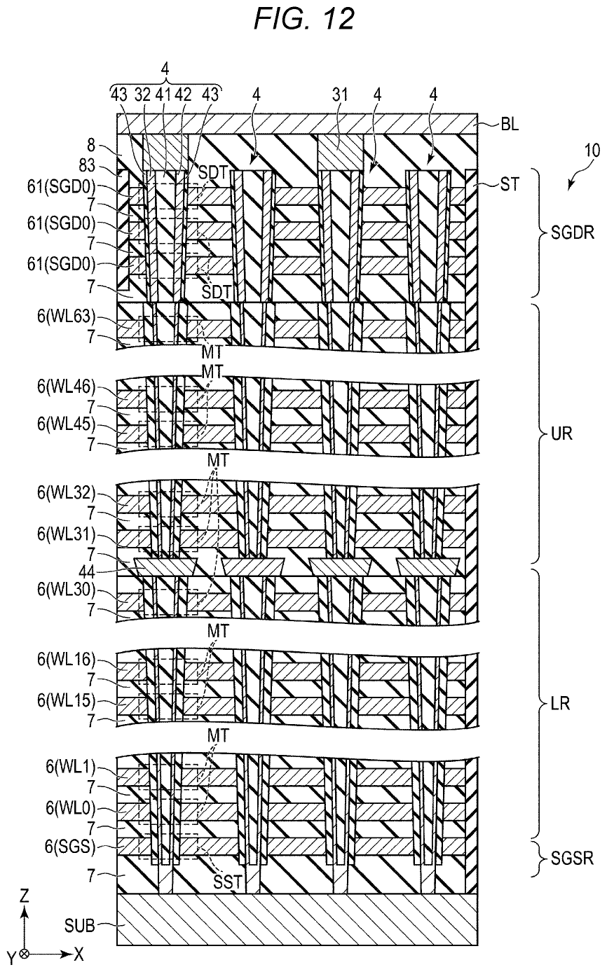

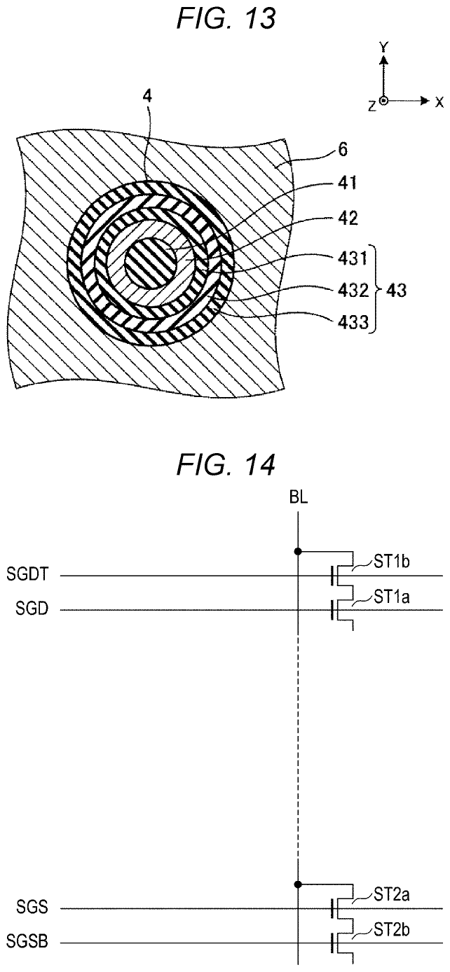

FIG. 10 is a perspective view schematically illustrating a part of the NAND flash memory 1 (a part including one plane) according to the embodiment. FIG. 11 is an XY plan view illustrating the memory cell array 10 according to the embodiment. FIG. 12 is an ZX sectional view illustrating the memory cell array 10 according to the embodiment. FIG. 13 is an XY plan view illustrating the memory cell array 10 according to the embodiment.

In FIGS. 10, 11, 12, and 13, directions perpendicular to each other in a plane parallel to the surface of a semiconductor substrate SUB are X and Y directions. More specifically, the X direction is a direction in which the word line WL extends and the Y direction is a direction in which the bit line BL extends. The Z direction is a direction perpendicular to the surface of the semiconductor substrate SUB.

As illustrated in FIG. 10, the NAND flash memory 1 includes the select gates SGS, the word lines WL, and the select gates SGD. The select gates SGS are stacked above the semiconductor substrate SUB with an interlayer insulating film 7 interposed therebetween. In the example of FIG. 10, the select gates SGS are provided in three layers. The word lines WL are stacked above the select gate SGS of the uppermost layer with an interlayer insulating film 7 interposed therebetween. In the example of FIG. 10, the select gates SGD0 and SGD1 divided in the Y direction are illustrated. The select gates SGD are stacked above the word line WL of the uppermost layer with an interlayer insulating film 7 interposed therebetween. The select gates SGS, the word lines WL, and the select gates SGD are each in a plate shape extending in the X and Y directions.

In the example of FIG. 10, the select gates SGD, the word lines WL, and the select gates SGS are segmented to be insulated from each other by a slit ST in the Y direction. The slit ST is provided above the semiconductor substrate SUB and extends in the X and Z directions.

The select gates SGD are segmented, for example, in the Y direction by an insulating layer 83. The insulating layer 83 is provided above (+Z side) of the word line WL and extends in the X and Z directions. Therefore, select gates SGD0 and SGD1 are arranged side by side in the Y direction above the word line WL. In the example of FIG. 10, the select gates SGD0 and SGD1 are each provided in three layers.

The semiconductor substrate SUB is, for example, a silicon substrate. The select gates SGS, the word lines WL, and the select gates SGD are, for example, metal layers containing tungsten (W) or molybdenum (Mo). The interlayer insulating film 7 and the insulating layer 83 are, for example, insulators containing silicon oxide.

The NAND flash memory 1 further includes a plurality of columnar bodies 4. The columnar bodies 4 penetrate through the select gates SGS, the word lines WL, and the select gates SGD and extend in the Z direction that is a stacking direction. The NAND flash memory 1 further includes a plurality of bit lines BL and source lines SL provided above the select gates SGD.

Each of the columnar bodies 4 is electrically connected to the bit line BL via a contact plug 31. For example, one of the columnar bodies 4 sharing the select gate SGD0 and one of the columnar bodies 4 sharing the select gate SGD1 are electrically connected to one bit line BL. In FIG. 10, to facilitate the illustration, an interlayer insulating film provided between the select gate SGD and the bit line BL is not illustrated.

In the case of the NAND flash memory 1 that has a 3-dimensional structure, a portion in which the word line WL and the columnar body 4 intersect each other functions as a memory cell, and the memory cell array 10 in which the plurality of memory cells are arrayed 3-dimensionally is configured. A portion in which the select gate SGS and the columnar body 4 intersect each other functions as a source-side select gate transistor, and a portion in which the select gates SGD0 and SGD1 and the columnar body 4 intersect each other functions as a drain-side select gate transistor. In the NAND flash memory 1, by increasing the number of stacked layers of the word line WL in a stacked body, it is possible to increase a storage capacity without using a more minute patterning technique.

As illustrated in FIGS. 10 and 11, the memory cell array 10 is configured as array of the 3-dimensional memory cell transistors in which the columnar bodies 4 are arrayed 2-dimensionally in the X and Y directions on the +Z side of the semiconductor substrate SUB, and the word lines WL of the plurality of layers are penetrated by the columnar bodies 4.

As illustrated in FIG. 11, in an XY plan view, the plurality of columnar bodies 4 are disposed to configure a plurality of columns. Each column extends in the X direction. In columns close to each other in the Y direction among the plurality of columns, disposition positions of the columnar bodies 4 are shifted from each other by a substantial half of a disposition pitch in the X direction. In an XY plan view, the plurality of columnar bodies 4 can also be seen to be arrayed in a staggered arrangement. Each columnar body 4 corresponds to a plurality of memory cell transistors arrayed in the Z direction.

Each conductive layer serving as the select gate SGD is segmented (divided) into a plurality of drive electrode films 61 by the insulating film (second segmented film) 83 with a substantial plate shape extending in the X and Z directions. The drive electrode films 61 can be formed of a material that has a conductive material as a main component. The conductive material includes tungsten or molybdenum that is metal.

As one of reasons that the threshold voltage distribution of the memory cell transistors in the edge block is different from the threshold voltage distribution of the memory cell transistors in the middle block, it is conceivable that dimensions of the drive electrode films 61 in the X direction are not constant in the Z direction. As a reason that the dimensions of the drive electrode films 61 in the X direction are not constant, it is conceivable that dimensions of the widths of grooves (dimensions in the X direction) are not constant in a depth direction (−Z direction) of the grooves in a process of forming the grooves in which the insulating film 83 is buried.

As another reason that the threshold voltage distribution of the memory cell transistors in the edge block is different from the threshold voltage distribution of the memory cell transistors in the middle block, it is conceivable that the dimensions of the columnar body 4 in the X direction are not constant in the Z direction. As a reason that the dimensions of the columnar bodies 4 in the X direction are not constant, it is conceivable that dimensions of the widths of grooves (dimensions in the X direction) are not constant in the depth direction (−Z direction) of the grooves in a process of forming the grooves in which the insulating film 83 is buried.

In the memory cell array 10, a conductive layer 6 and an insulating layer 7 are stacked alternately, and a drive electrode film 61 and the insulating layer 7 are further stacked alternately.

The conductive layer 6 can be formed of a material that has a conductive material as a main component. The conductive material includes, for example, tungsten or molybdenum that is metal. The conductive layer 6 functions as the word line WL.

Each insulating layer 7 can be formed of a material that has an insulating material as a main component. The insulating material is, for example, silicon oxide that is semiconductor oxide.

In the memory cell array 10, the columnar bodies 4 includes a core insulating film 41, a semiconductor channel 42, and an insulating film 43. The core insulating film 41 can be formed of a material that has an insulating material (for example, silicon oxide) as a main component. The semiconductor channel 42 has a substantially cylindrical shape extending in a central axis of the columnar body 4 disposed to surround the core insulating film 41 from the outside.

The semiconductor channel 42 includes a channel region in a memory string MS. The semiconductor channel 42 can be formed of a material that has single-crystal silicon, amorphous silicon, or polysilicon as a main component.

The insulating film 43 is disposed between the drive electrode film 61 or the conductive layer 6 (the word line WL) and the semiconductor channel 42. The insulating film 43 covers a side surface of the semiconductor channel 42. The insulating film 43 has a charge storage capability in a portion disposed between the conductive layer 6 (the word line WL) and the semiconductor channel 42.

As illustrated in FIG. 13, the insulating film 43 can have a three-layered structure of a tunnel insulating film 431, a charge storage film 432, and a block insulating film 433 in order from the semiconductor channel 42 side. The tunnel insulating film 431 can be formed of a material that has an oxide (for example, a silicon oxide) as a main component. The charge storage film 432 can be formed of a material that has a nitride (for example, a silicon nitride) as a main component. The block insulating film 433 can be formed of a material that has an oxide (for example, a silicon oxide, a metal oxide, or a stacked layer thereof) as a main component.

In the memory cell array 10, a plurality of columnar structures (also referred to as tiers) are stacked with a semiconductor film 44 interposed therebetween to form the columnar body 4. In FIG. 12, a case where the columnar body 4 is formed by two tiers is illustrated as an example. The semiconductor film 44 is electrically connected to each of the semiconductor channels 42 of the upper and lower tiers. The memory cell array 10 includes regions UR and LR divided in the Z direction to correspond to the two tiers.

In FIG. 12, the region UR is a region corresponding to the upper tier. The region UR is a region on the +Z side of the region LR. The region UR corresponds to a first memory region MR1 in FIG. 9. The region LR is a region corresponding to the lower tier. The region LR corresponds to a second memory region MR2 in FIG. 9. The region SGDR is a region corresponding to the select transistor SDT. The region SGDR is disposed on the +Z side of the region UR. The region SGSR is a region corresponding to the select transistor SGS. The region SGSR is disposed on the −Z side of the region LR.

In the case of the NAND flash memory illustrated in FIGS. 10 to 12, unlike a planar NAND flash memory in which a channel of a control gate is directly connected to a substrate, an erase operation is executed by raising a channel potential under a control gate with a Hall current of a gate induced drain leakage (GIDL) occurring in a channel at a select gate end.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device comprising:
a bit line extending in a first direction;
a memory cell array region including a first region including a first block, a second region including a second block, and a third region disposed between the first region and the second regions and including a third block, each of the first to third blocks being configured an erasing unit, wherein the first region, the second region, and the third region are disposed in the first direction and each of the first block, the second block, and the third block includes a plurality of memory transistors to store data; and
a storage unit configured to store a parameter regarding a first erasing voltage applied to the first block and the second block during an erase operation on the first block and the second block and a second erasing voltage applied to the third block during an erase operation on the third block, wherein the first erasing voltage is different from the second erasing voltage,
wherein the first region is disposed on an edge side of the memory cell array region in a direction opposite to the first direction, and
wherein the second region is disposed on an edge side of the memory cell array region in the first direction.

2. The memory device according to claim 1,
wherein, when a threshold voltage of the plurality of memory transistors in the first block is higher than a threshold voltage of the plurality of memory transistors in the third block and a threshold voltage of the plurality of memory transistors in the second block is higher than the threshold voltage of the plurality of memory transistors in the third block, the first erasing voltage is higher than the second erasing voltage, and
wherein, when the threshold voltage of the plurality of memory transistors in the first block is lower than the threshold voltage of the plurality of memory transistors in the third block and the threshold voltage of the plurality of memory transistors in the second block is lower than the threshold voltage of the plurality of memory transistors in the third block, the first erasing voltage is lower than the second erasing voltage.

3. The memory device according to claim 2,
wherein the memory cell array region further includes a fourth region including a fourth block and a fifth region including a fifth block, each of the fourth block and the fifth block being configured an erasing unit,
wherein the fourth region is disposed between the first region and the third region,
wherein the fifth region is disposed between the second region and the third region,
wherein the fourth region and the fifth region are disposed in the first direction and each of the fourth block and the fifth block includes a plurality of memory transistors to store data,
wherein the parameter further includes an erasing voltage applied to the fourth block during an erase operation on the fourth block and an erasing voltage applied to the fifth block during an erase operation on the fifth block, and
wherein the erasing voltage applied to the fourth block and the erasing voltage applied to the fifth block are each equal to the second erasing voltage.

4. The memory device according to claim 3, further comprising a plurality of the memory cell array regions.

5. A controlling method of a memory device, the memory device comprising:
providing a bit line extending in a first direction and a memory cell array region including a first region including a first block, a second region including a second block, and a third region disposed between the first region and the second region and including a third block, each of the first to third blocks being configured as an erasing unit, wherein the first region, the second region, and the third region are disposed in the first direction and each of the first block, the second block, and the third block includes a plurality of memory transistors to store data,
wherein the first region is disposed on an edge side of the memory cell array region in a direction opposite to the first direction;
wherein the second region is disposed on an edge side of the memory cell array region in the first direction,
wherein the method comprises:
applying a first erasing voltage to the first block during an erase operation on the first block;
applying the first erasing voltage to the second block during an erase operation on the second block; and
applying a second erasing voltage to the third block during an erase operation on the third block,
wherein the first erasing voltage is different from the second erasing voltage.

6. The controlling method of the memory device according to claim 5,
wherein the memory cell array region further includes a fourth region including a fourth block and a fifth region including a fifth block, each of the fourth block and the fifth block being configured as an erasing unit
wherein the fourth region is disposed between the first region and the third region;
wherein the fifth region is disposed between the second region and the third region;
wherein the fourth region and the fifth region are disposed in the first direction, wherein each of the fourth block and the fifth block includes a plurality of memory transistors to store data; the method further comprises:
applying the second erasing voltage to the fourth block during an erase operation on the fourth block; and
applying the second erasing voltage to the fifth block during an erase operation on the fifth block.

7. The controlling method of the memory device according to claim 6,
wherein the memory device include a plurality of the memory cell array regions,
wherein the method further comprises:
applying a first erasing voltage to the first block during erasing on the first block of each of the plurality of memory cell array regions;
applying the first erasing voltage to the second block during erasing on the second block of each of the plurality of memory cell array regions;
applying the second erasing voltage to the third block during erasing on the third block of each of the plurality of memory cell array regions;
applying the second erasing voltage to the fourth block during erasing on the fourth block of each of the plurality of memory cell array regions, and
applying the second erasing voltage to the fifth block during erasing on the fifth block of each of the plurality of memory cell array regions.

8. The controlling method of the memory device according to claim 7,
wherein, when a threshold voltage of the plurality of memory transistors in the first block and a threshold voltage of the plurality of memory transistors in the second block are higher than a threshold voltage of the plurality of memory transistors in the third block, the fourth block, or the fifth block, the first erasing voltage is higher than the second erasing voltage, and
wherein, when the threshold voltage of the plurality of memory transistors in the first block and the threshold voltage of the plurality of memory transistors in the second block are lower than the threshold voltage of the plurality of memory transistors in the third block, the fourth block, or the fifth block, the first erasing voltage is lower than the second erasing voltage.
